(19) United States
(12) Patent Application Publication
(10) Pub. No.: US 2009/0321713 A1
(43) Pub. Date: Dec. 31, 2009

(54) METHOD OF CONTROLLING ACTIVE LAYER OF III-NITRIDE SEMICONDUCTOR LIGHT EMITTING DEVICE

(76) Inventors: Tae Kyung Yoo, Kyunggi-do (KR); Eun Hyun Park, Kyunggi-do (KR)

Correspondence Address: HARNESS, DICKEY, & PIERCE, P.L.C, 7700 Bonhomme, Suite 400, ST. LOUIS, MO, 63105, US

(21) Appl. No.: 11/988,495

(22) PCT Filed: Oct. 18, 2005
(86) PCT No.: PCT/KR2005/003470

§ 371 Date: Sep. 8, 2009

(30) Foreign Application Priority Data
Jul. 6, 2005 (KR) 10-2005-0060807

(51) Int. Cl. H01L 33/00

(52) U.S. Cl. 257/13; 257/E33.008

(57) ABSTRACT

The present invention is to provide a method for controlling an active layer of a Hi-nitride semiconductor light emitting device by doping a barrier layer(s) selected from the active layer to suppress light emission in a specific well layer(s).

### TECHNICAL FIELD

The present invention relates to a method for controlling an active layer of a III-nitride semiconductor light emitting device, and more particularly, a method for emitting light mainly in an intended well layer(s) by doping a barrier layer(s) selected from active layers to form a hole barrier.

Here, the III-nitride semiconductor light emitting device means a light emitting device such as a light emitting diode comprising a compound semiconductor layer of Al(x)Ga(y)In(1-x-y)N (0≦x≦1, 0≦y≦1, 0≦x+y≦1), which may further comprise a compound of elements from other groups such as SiC, SiN and SiCN, CN or a semi-conductor layer of the compound.

### BACKGROUND ART

FIG. 1 is a view for illustrating a conventional III-nitride semiconductor light emitting device. The light emitting device comprises a substrate 100, a buffer layer 200 epitaxially grown on the substrate 100, an n-type nitride semiconductor layer 300 epitaxially grown on the buffer layer 200, an active layer 400 epitaxially grown on the n-type nitride semiconductor layer 300, a p-type nitride semiconductor layer 500 epitaxially grown on the active layer 400, a p-side electrode 600 formed on the p-type nitride semiconductor layer 500, a p-side bonding pad 700 formed on the p-side electrode 600, and an n-side electrode 800 formed on an n-type nitride semiconductor layer 301 exposed by mesa etching of at least the p-type nitride semiconductor layer 500 and the active layer 400.

The substrate 100 may be a homogeneous substrate such as a GaN type substrate, a heterogeneous substrate such as a sapphire substrate, a SiC substrate or a Si substrate, though any type of substrate can be used as long as the nitride semiconductor layer can grow.

The nitride semiconductor layers epitaxially grown on the substrate 100 are mostly grown by MOCVD (Metal-Organic Chemical Vapour Deposition).

The buffer layer 200 is to cope with the difference of lattice constant and coefficient of thermal expansion between a heterogeneous substrate 100 and a nitride semi-conductor, U.S. Pat. No. 5,122,845 discloses a technique for growing an AlN buffer layer to thickness of 100 Å to 500 Å on a sapphire substrate at a temperature of 380° C. to 800° C., U.S. Pat. No. 5,290,393 discloses a technique for growing an Al(x)Ga(1-x)N (0≦x<1) buffer layer to a thickness of 10 Å to 50000 Å on a sapphire substrate at a temperature of 200° C. to 900° C. and International Patent Publication WO/05/053042 discloses a technique for growing an In(x)Ga(1-x)N (0<x≦1) layer on a SiC buffer layer (seed layer) grown at a temperature of 600° C. to 990° C.

The n-type nitride semiconductor layer 300 is doped with an impurity at least at the area at which the n-side electrode 800 is formed (n-type contact layer) and the n-type contact layer preferably consists of GaN and is doped with Si. U.S. Pat. No. 5,733,796 discloses a technique for doping an n-type contact layer at a desired doping concentration by adjusting a mixing ratio of Si and other source material.

The active layer 400 is a layer for producing protons (light) by recombination of electrons and holes, mainly formed of In(x)Ga(1-x)N (0<x≦1), and comprises a single quantum well layer or a multi quantum well layer. International Patent Publication WO/02/021121 discloses a technique for doping only a part of the multi quantum well layer and barrier layer.

The p-type nitride semiconductor layer 500 is doped with a proper impurity such as Mg and has a p-type electro-conductivity via the activation process. U.S. Pat. No. 5,247,533 discloses a technique for activating a p-type nitride semiconductor layer by application of electron beam, U.S. Pat. No. 5,306,662 discloses a technique for activating a p-type nitride semiconductor layer by annealing at a temperature of 400° C. or more and International Patent Publication WO/05/022655 discloses a technique for providing a p-type nitride semiconductor layer with p-type electroconductivity without any activation process by using ammonia and hydrazine-based source material together as a nitrogen precursor in growing the p-type nitride semiconductor layer.

The p-side electrode 600 is provided for smooth supply of electric current throughout the p-type nitride semiconductor layer 500. U.S. Pat. No. 5,563,422 discloses a technique on an transparent electrode of Ni and Au, formed on the almost entire surface of a p-type nitride semiconductor layer and ohmically contacting with the p-type nitride semiconductor layer and U.S. Pat. No. 6,515,306 discloses a technique for forming a transparent electrode of ITO (Indium Tin Oxide) on an n-type super lattice layer which is formed on a p-type nitride semiconductor layer.

Meanwhile, the p-side electrode 600 may be formed to have a thickness so that light cannot be transmitted, that is, light can be reflected to the substrate side. A light emitting device using such a thick p-side electrode 600 is called a flip chip. U.S. Pat. No. 6,194,743 discloses a technique of an electrode structure comprising an Ag layer having a thickness of 20 nm or more, a diffusion barrier layer covering the Ag layer and a bonding layer of Au and Al covering the diffusion barrier layer.

The p-side bonding pad 700 and the n-side electrode 800 are used for supply of electric current and wire bonding to the outside. U.S. Pat. No. 5,563,422 discloses an n-side electrode 800 comprising Ti and Al and U.S. Pat. No. 5,652,434 discloses a p-side bonding pad directly contacting a p-type nitride semiconductor layer by partial removal of a transparent electrode.

Generally, a light emitting device emits light by conversion of electric energy to light energy through recombination of electrons and holes in a quantum well layer(s) of an active layer. Here, how efficiently electrons and holes combines with each other determines the internal quantum efficiency in the light emitting device.

In case of a III-nitride semiconductor light emitting device, as compared to other compound semiconductors, the hole mobility (10-20) is significantly lower than the electron mobility (200-500) and thus, the hole mobility in an active layer has a great effect on the performance of the light emitting device.

It was a difficult subject to produce a p-type in the early stage of development of the III-nitride light emitting device. As described above, the p-type GaN is produced by removing hydrogen (H) bonded to magnesium (Mg) through thermal treatment (annealing) or application of electron beam. Also, the present inventors have proposed a method for producing a p-type GaN by removing hydrogen (H) using a Hydrazine-based source.

As described above, there have been proposed various methods for producing a p-type GaN in a III-nitride semiconductor light emitting device. However, it is still hard to produce a p-type GaN with a hole concentration of 10¹⁸ or more.

Also, the hole mobility is 10-20, which is much lower than the electron mobility of 200-500. Considering the mobility and the conductivity are directly proportional to each other, the low mobility means low electric conductivity of holes. Therefore, the low electric conductivity by holes in a III-nitride semiconductor light emitting device causes a larger light emitting device resistivity in a p-type layer than that in an n-type layer.

The present inventors have researched the effect of the low hole mobility, which is one of properties of the III-nitride semiconductor light emitting device, obtained an interesting result and found that light emission characteristic of the III-nitride semi-conductor light emitting device can be improved using the result.

### DISCLOSURE OF INVENTION

### Technical Problem

Accordingly, it is an object of the present invention to provide a method for controlling an active layer of a III-nitride semiconductor light emitting device by doping a barrier layer(s) selected from the active layer to suppress light emission in a specific well layer(s).

Also, it is another object of the present invention to provide a method for controlling an active layer of a III-nitride semiconductor light emitting device by doping a barrier layer(s) selected from the active layer to form a hole barrier (layer) so that major light emission occurs in an intended well layer(s).

It is a further object of the present invention to provide a method for controlling an active layer of a III-nitride semiconductor light emitting device which can be variously applied for many purposes by selectively controlling a well layer which can emit light in an active layer.

### Technical Solution

To accomplish the above objects of the present invention, according to the present invention, there is provided a method for controlling an active layer of a III-nitride semiconductor light emitting device comprising: a substrate; and a plurality of nitride semiconductor layers, grown on the substrate, the nitride semiconductors comprising a first nitride semiconductor layer, to which a first electrode is electrically contacted, a second nitride semiconductor layer, to which a second electrode is electrically connected, and an active layer disposed between the first nitride semiconductor layer and the second nitride semiconductor layer to produce light by recombination of electrons and holes, wherein the active layer has a structure comprising quantum well layers and at least one barrier layer which are alternately stacked, in which the number of the quantum well layers is n (n≧2, n is an integer), the iₜₕ quantum well layer (1≦i≦n, i is an integer) from the upper side of the active layer has a band gap energy (Eᵢ) and the barrier layer disposed under the jₜₕ quantum well layer (1≦j≦n−1, j is an integer) is doped, so the kₜₕ quantum well layer (j+1≦k≦n, k is an integer) is inhibited from emitting light having a wavelength corresponding an band gap energy (Eₖ) of the kₜₕ quantum well layer.

Also, according to the present invention, there is provided a method for controlling an active layer of a III-nitride semiconductor light emitting device comprising: a substrate; and a plurality of nitride semiconductor layers, grown on the substrate, the nitride semiconductors comprising a 1ₜₕ nitride semiconductor layer, to which a first electrode is contacted, a second nitride semiconductor layer, to which a second electrode is connected, and an active layer disposed between the first nitride semi-conductor layer and the second nitride semiconductor layer to produce light by re-combination of electrons and holes, wherein the active layer has a structure comprising quantum well layers and barrier layers which are alternately stacked, in which the number of the quantum well layers is n(n≧2, n is an integer), the iₜₕ quantum well layer (1≦i≦n, i is an integer) from the active layer has a band gap energy (Eᵢ) and a barrier layer disposed under the jₜₕ quantum well layer (1≦j≦n−1, j is an integer) is doped, so light emission from the 1ₜₕ quantum well layer to the jₜₕ quantum well layer forms a major portion of the total light emission of the III-nitride semiconductor light emitting device.

Also, according to the present invention, there is provided a method for controlling an active layer of a III-nitride semiconductor light emitting device by selecting a light emitting quantum well layer by doping of a barrier layer. That is, since the major portion of light emission occurs in the intended quantum well layer(s), it is possible to improve properties of the light emitting device by treating only the intended quantum well layer(s).

Also, the present invention provides method for controlling an active layer of a III-nitride semiconductor light emitting device, in which the distance between the jₜₕ quantum well layer (1≦j≦n−1, j is an integer) and the 1ₜₕ quantum well layer is not greater than the distance between the jₜₕ quantum well layer (1≦j≦n−1, j is an integer) and the nₜₕ quantum well layer. According to this, a major light emission area located at the center of the active layer can be shifted to the quantum well layer(s) disposed over the active layer.

### Advantageous Effects

According to the present invention, it is possible to improve light emitting characteristics of a III-nitride semiconductor light emitting device by doping a barrier layer(s) selected from an active layer to suppress light emission in a specific well layer(s) and by forming a hole barrier to cause the major light emission occur in an intended well layer(s).

Also, according to the present invention, it is possible to provide a technical ground which can be variously applied for many purposes by selectively controlling a well layer which can emit light in an active layer.

### BRIEF DESCRIPTION OF THE DRAWINGS

Further objects and advantages of the invention can be more fully understood from the following detailed description taken in conjunction with the accompanying drawings in which:

FIG. 1 is a cross sectional view for illustrating a conventional III-nitride semi-conductor light emitting device;

FIG. 2 is a view for illustrating an example of an active layer used for explaining the present invention;

FIG. 3 is a view for illustrating Samples 1-4 according to the present invention;

FIG. 4 shows the result of the spectrum analysis of Samples 1-4 according to the present invention;

FIG. 5 is a view for illustrating Samples 5-6 according to the present invention;

FIG. 6 shows the result of the spectrum analysis of Samples 5-6 according to the present invention and Comparative Samples 1-2; and

FIG. 7 is a view for illustrating Embodiment 1 according to the present invention.

### MODE FOR THE INVENTION

Now, the present invention is described in detail.

In order to examine the role and contribution to light emission of each well layer in an active layer in the multi-quantum well layer structure, the active layer is constructed to have five well layers as shown in FIG. 2, band gap energies of the conduction band and the valence band are shown. The well layers are represented by W and the barrier layers are represented by B, each starting from the p-type GaN layer side (p-side in FIG. 2) to the n-side (n-side in FIG. 2), each well layer (W:1, W:2, W:3, W:4, W:5) and each barrier layer (B:1,B:2,B:3,B:4,B:5,B:6) is numbered from the p-side, as shown in FIG. 2.

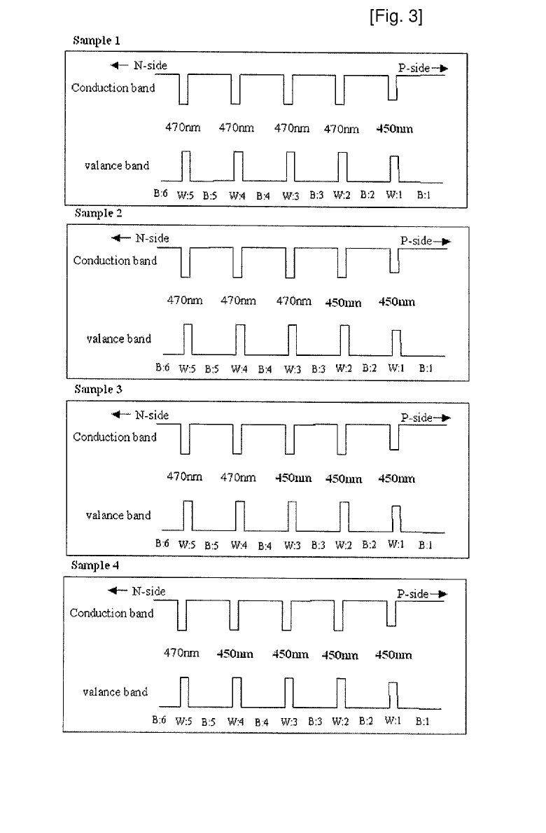

In order to distinguish characteristics of well layers (W:1, W:2, W:3, W:4, W:5), various samples of well layers of the active layer are prepared, as shown in FIG. 3. Each well layer has a thickness of about 30 Å and each barrier layer has a thickness of about 100 Å.

In Sample 1, the first well layer (W:1) has a band gap of about 450 nm and the remaining well layers (W:2˜W:5) have a wavelength of about 470 nm.

In Sample 2, the first and the second well layers (W:1, W:2) have a band gap of about 450 nm and the remaining well layers (W:3˜W:5) have a wave length of about 470 nm.

In Sample 3, the first, the second and the third well layers (W:1, W:2, W:3) have a band gap of about 450 nm and the remaining well layers (W:4˜W:5) have a wave length of about 470 nm.

In Sample 4, the first, the second, the third and the fourth well layers (W:1, W:2, W:3, W:4) have a band gap of about 450 nm and the remaining well layer (W:5) has a wave length of about 470 nm.

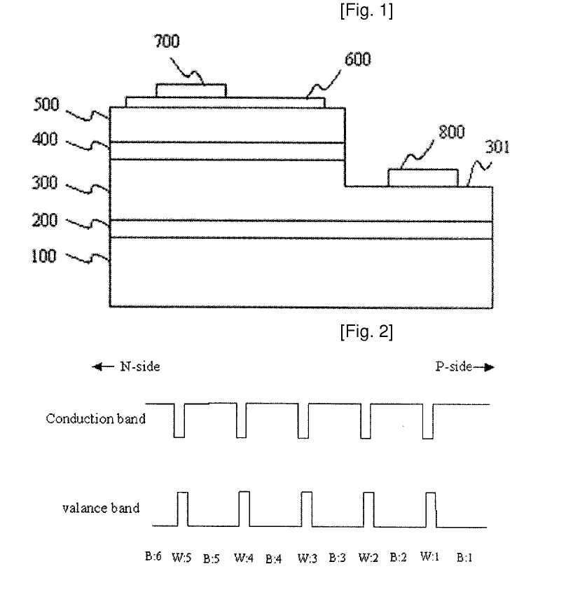

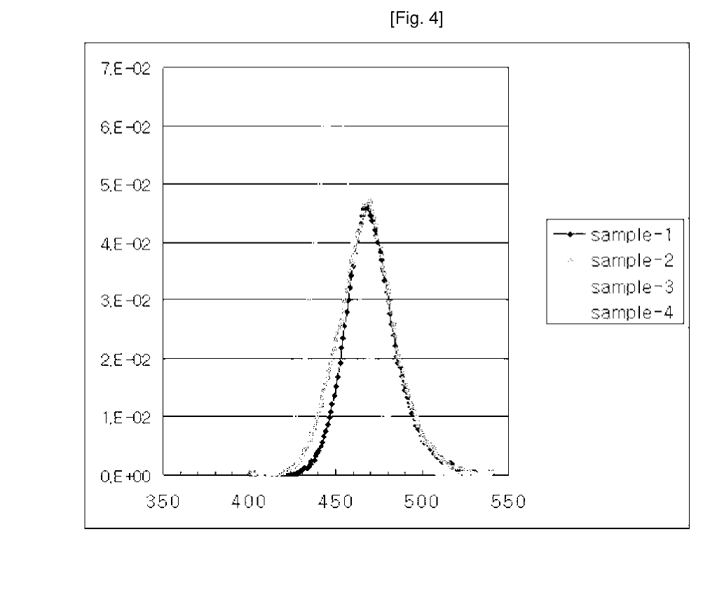

Light emitting devices are prepared using Samples 1-4 according to a method for preparation a common III-nitride semiconductor light emitting device, as shown in FIG. 1. 20 mA electric current is injected to each device and the spectrum of light emitted from each sample is measured, as shown in FIG. 4. The above-described sample sets are constructed to observe the shifting of the center of the light emission by forming well layers having different wavelengths sequentially from the p-side. Since the well layers have different efficiencies according to wavelength, the wavelengths should be close to each other if possible. Considering separate observation of the wavelengths, the well layers have two wavelengths of 450 nm and 470 nm.

Wavelength of light emitted from the p-side is measured with a spectrometer.

Sample 1

As shown in FIG. 3, Sample 1 comprises the last well layer of 450 nm and the rest of 470 nm. A light emitting device was prepared and the spectrum of Sample 1 was measured. As shown in FIG. 4, only the 470 nm wavelength light was observed while the 450 nm wavelength light was very faint or not observed. It is shown that the light emission in the last well layer (W:1) was very weak.

Sample 2

As shown in FIG. 3, Sample 2 comprises two from the last well layers of 450 nm and the rest of 470 nm. A light emitting device was prepared and the spectrum of Sample 2 was measured. As shown in FIG. 4, the 470 nm wavelength was observed as a main peak and a shoulder was observed near 450 nm. The shoulder part was definitely recognized as compared to Sample 1. It was shown that the second well layer from the last (W:2) contributed to the light emission, however, the intensity of the light emission is weak as compared to the main peak.

Sample 3

As shown in FIG. 3, Sample 3 comprises three from the last well layers of 450 nm and the rest of 470 nm. A light emitting device was prepared and the spectrum of Sample 3 was measured. As shown in FIG. 4, a main peak was observed at the 450 nm side and a weak light emission was observed by a shoulder near 470 nm. As compared to Sample 4, the weak shoulder was recognized for sure.

Sample 4

As shown in FIG. 3, Sample 4 comprises four from the last well layers of 450 nm and the remaining one well layer of 470 nm. A light emitting device was prepared and the spectrum of Sample 4 was measured. As shown in FIG. 4, a main peak was observed at 450 nm while weak light emission was observed near 470 nm. It was noted that the W:5 well layer did not contribute to the light emission.

Upon analysis of the results of Samples 1 to 4, it was noted that the third well layer from the last (W:3) played a critical role in the light emission while the fourth well layer (W:4) and the fifth well layer (W5) hardly contributed to the light emission.

It is believed that this was because the III-nitride semiconductor light emitting device had a very low hole mobility. Due to such low hole mobility, the holes mainly combined with electron before they got W:4, W:5.

One of the reasons the major light emission occurred in W:3 not in W:2 or W:1 is that the mobility of the electrons coming from the n-side is much greater than the holes but the pathway of electrons is obstructed by an electron spike barrier formed between the well layer and the barrier layer. Therefore, the well layers (W:1, W:2) disposed in front of the active layer hardly contributed to the light emission.

From the foregoing experiments, it was found that when a weak hole barrier was provided in the middle of the active layer, holes could be easily trapped in a certain well layer(s) due to the low hole mobility of the nitride semiconductor. In other words, it is possible to let major light emission intentionally occur in a certain well layer(s) of the active layer, so it would improve characteristics of light emitting devices and be applied in nitride light emitting devices for various purposes. In order to prove such idea, Sample 5 and Sample 6 were constructed.

Sample 5

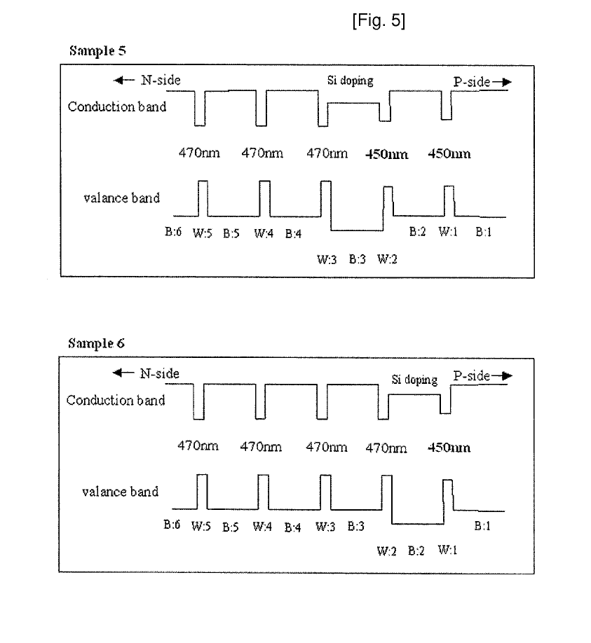

The third barrier layer (B:3) of Sample 2 was doped with silicon. The doping concentration was set to about 5×10¹⁷ to 1×10¹⁸. As shown in FIG. 5, B:3 was used as a hole barrier layer.

Sample 6

The second barrier layer (B:2) of Sample 1 was doped with silicon. The doping concentration was set to about 5×10¹⁷ to 1×10¹⁸. As shown in FIG. 5, B:2 was used as a hole barrier layer.

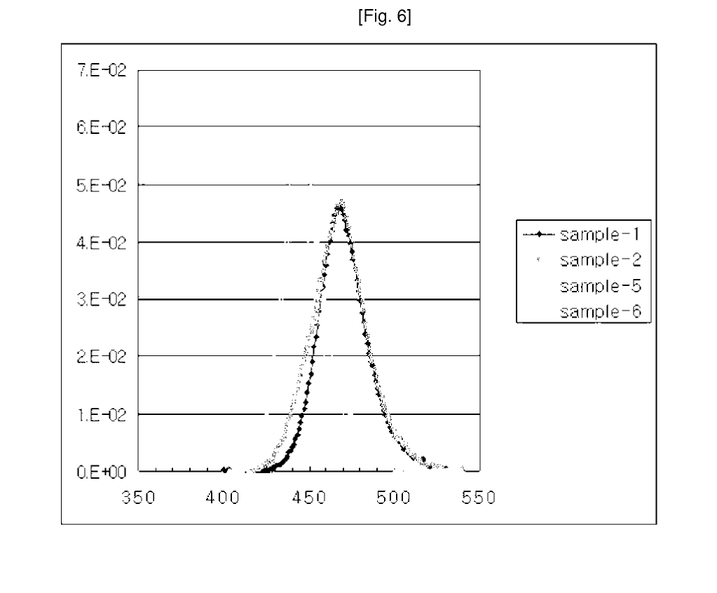

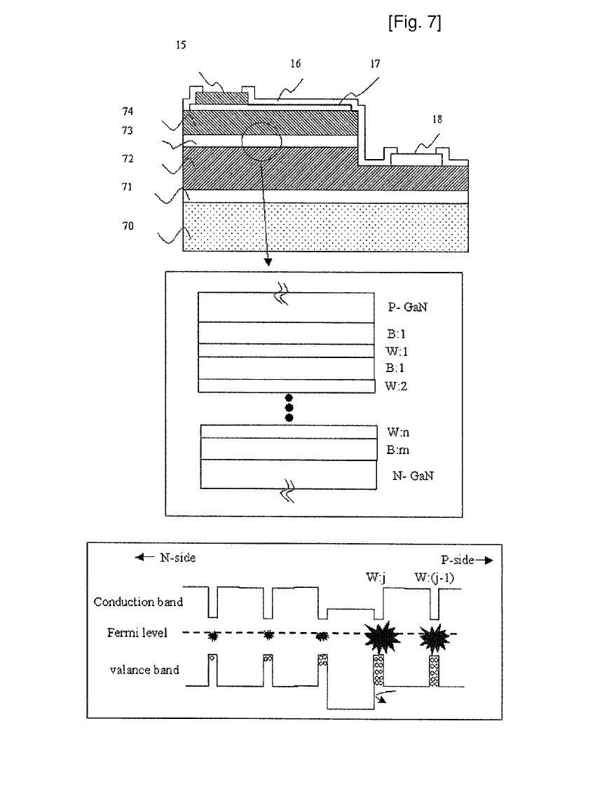

On the expectation that through the formation of a hole barrier (layer) by silicon doping, a barrier could be formed in the pathway of holes due to the low hole mobility of nitride semiconductors and subsequently, it was possible to intentionally control a major light emitting well layer(s) in the active layer, light emitting devices were constructed using Samples 5 and 6. The configuration of the light emitting devices and the method for preparation thereof were the same as for Samples 1-4. FIG. 6 shows the spectra of these samples.

Sample 5

As shown in FIG. 5, Sample 5 comprises two of the last well layers of 450 nm and the rest of 470 nm and the third barrier layer was doped with silicon. A light emitting device was prepared and the spectrum of Sample 5 was measured. As shown in FIG. 6, only the 450 nm wavelength was observed while little light of the 470 nm wavelength was observed. This sample had the same structure as that of Sample 2 except that the third barrier layer was doped with silicon. However, Sample 2 had a major light emission at 470 nm while Sample 5 had a major light emission at 450 nm. This is because, as expected above, the state of the energy band of the third barrier layer was changed by silicon doping and a new hole barrier was formed, whereby holes were trapped in the third well layer, due to the low mobility. It was believed that since the second well layer and the first well layer had the energy band at 450 nm wavelength, the major light emission occurred at 450 nm.

Sample 6

In order to check the result of Sample 5 for sure, Sample 6 was prepared.

As shown in FIG. 5, Sample 6 comprised the last well layer of 450 nm and the rest of 470 nm and the second barrier layer was doped with silicon. A light emitting device was prepared and the spectrum of Sample 6 was measured. As shown in FIG. 6, only the 450 nm wavelength was observed while little light of the 470 nm wavelength was observed. This sample had the same structure as that of Sample 1 except that the second barrier layer was doped with silicon. However, Sample 1 had a major light emission 470 nm without faint emission at 450 nm while Sample 6 had a major light emission a 450 nm without light emission at 470 nm. This is because, as expected above, the state of the energy band of the second barrier layer was changed by silicon doping and a new hole barrier (layer) was formed, whereby holes are trapped in the first well layer, due to the low mobility. It was believed that since the first well layer had energy band at 450 nm wavelength, the major light emission occurred at 450 nm.

The summary of the results of Sample 5 and Sample 6 is as follows.

By formation of n-type through doping on a selected barrier layer(s), a hole barrier (layer) was formed. Due to the low hole mobility of the nitride semiconductor, holes were easily trapped in a well layer(s) in front of the hole barrier (layer) and subsequently, the major light emission occurs in the intended well layer(s). By the results of Sample 5 and Sample 6, the foregoing disclosure was experimentally proven. By this technique, it is possible to let major light emission intentionally occur in a certain well layer(s) of the active layer, so it would improve characteristics of light emitting devices and be applied in nitride light emitting devices for various purposes.

Though the silicon doping on a barrier layer was used in the prior art, the silicon doping on a barrier layer was for facilitating movement of electrons to lower the operation voltage of the light emitting device or to improve the film quality by a weak doping. The present inventors, for the first time, have developed a technique for selective light emission in an active layer by n-type doping.

Now, the present invention is described using the following embodiments.

### EMBODIMENT 1

A buffer layer or seed layer 71 acting as a seed, an n-type nitride semiconductor layer 72, an active layer 73 of nitride semiconductors comprising quantum well layers and quantum barrier layers, and a p-type nitride semiconductor layer 74 are sequentially stacked on a substrate 70 of sapphire or SiC to form a light emitting device. As needed, each layer may include sub-layers. An n-side electrode 18 is formed on the etched n-type nitride semiconductor layer 72 and a p-side electrode 17 and a p-side bonding pad 15 are formed on the p-type nitride semiconductor layer 74. A protection layer 16 is formed thereon. When a SiC substrate is used, the n-side electrode 18 may be formed under the substrate 70.

The active layer comprises a barrier layer (B:1) and a well layer (W:1) which are alternately stacked from the p-type nitride semiconductor layer 74, in which the well layer is numbered starting from W:1 to the nₜₕ well layer of W:n and the barrier layer is numbered starting from B:1 to the mₜₕ barrier layer of W:m.

Of course, the barrier layer may be formed in a multi-layered structure including two or more layers, as needed. The term B:i used herein means the entire of the multiple layers when the barrier layer is formed in a multi-layered structure.

In order to let a major light emission of at least 70 to 80% or more (The skilled in the art would understand that this numerical value was not obtained by precise calculation but only a value presumed from the spectra of FIG. 4 and FIG. 6. In deed, 90% or more light was emitted in the selected quantum well layer(s) in FIG. 4 and FIG. 6) occur in the 1ₛₜ to the jₜₕ well layer starting from the p-side, the j+1ₜₕ barrier layer (when an active layer contacting the p-side is a barrier layer) or the jₜₕ barrier layer (when an active layer contacting the p-side was a well layer) is doped with an n-type dopant such as Si, C, Ge, Sn and the like. As a result, a hole barrier (layer) is formed and the light emitting parts are limited to the 1ₛₜ to jₜₕ layers since the nitride semiconductor had a low hole mobility. When j is 1, it is possible to excessively concentrate at least 70 to 80% of the total light emission of the light emitting device in the last well layer.

Here, the well layer may have a thickness of 5 Å to 50 Å and the barrier layer may have a thickness of 30 Å to 500 Å. The reason why the barrier layer has a thickness of 30 Å or more is that when it is too thin, holes can tunnel the barrier layer(s). And then the holes moves to the next well layer through the tunneling, it is hard to obtain a major light emission in an intentionally selected well layer(s). When the barrier layer has a thickness of 500 Å or more, the film quality may be deteriorated.

The doping concentration may be in the range of 5×10¹⁶ to 9×10¹⁹. When it is less than 5×10¹⁶, it is hard to form a hole barrier (layer). When it exceeds 9×10¹⁹, the film quality of the barrier layer may be deteriorated, thereby causing deterioration in performance of the light emitting device.

### EMBODIMENT 2

The method to form a hole barrier (layer) according to the Embodiment 1, wherein starting from the p-side from the j+1ₜₕ barrier layer (when an active layer contacting the p-side is a barrier layer) or the jₜₕ barrier layer (when an active layer contacting the p-side was a well layer) to the fₜₕ barrier layer (j<f≦m, m is the total number of barrier layers) are doped with an n-type dopant such as Si, C, Ge, Sn and the like, in order to let a major light emission of at least 70 to 80% or more occur in the 1ₛₜ to the jₜₕ well layer. By the doping to the fₜₕ barrier layer, the electron barrier is lowered, whereby the electron mobility is increased, further improving light emission efficiency in the selected well layer(s).

### EMBODIMENT 3

The method to form a hole barrier (layer) according to the Embodiment 1, wherein the j+1ₜₕ barrier layer (when an active layer contacting the p-side was a barrier layer) or the jₜₕ barrier layer (when an active layer contacting the p-side is a well layer) must be doped. And at least layer starting from this barrier layer to the fₜₕ barrier layer (j<f≦m, m is the total number of barrier layers) is doped with an n-type dopant such as Si, C, Ge, Sn and the like, in order to let a major light emission of at least 70 to 80% or more occur in the 1ₛₜ to the jₜₕ well layer starting from the p-side. In this case, by the doping on the selected barrier layers, the electron barrier is also lowered, whereby the electron mobility is increased, improving light emission efficiency in the selected well layer(s).

### EMBODIMENT 4

The method to form a hole barrier (layer) according to the Embodiment 1 to 3, wherein the barrier layer is partially doped with a thickness of 30 Å or more, when the barrier layer is doped with a thickness of 30 Å or more. For example, when the barrier layer has a thickness of 100 Å, the barrier layer is doped in such a manner that the doped portion of the certain barrier layer has a thickness of 30 Å to 100 Å. Here, the doped portion means the doping location is not limited in the barrier layer. That is, doped portion is composed of two of more sub-doped portion in the barrier layer and the sum of the thickness of the doped portion is 30 Å or.

### EMBODIMENT 5

The method to form a hole barrier (layer) according to the Embodiment 1 to 4, wherein the barrier layer has a multi-layered structure of different composition of Al(x)Ga(y)In(1-x-y)N (0≦x≦1, 0≦y≦1, 0≦x+y≦1).

1. A method for controlling an active layer of a III-nitride semiconductor light emitting device comprising: a substrate; and a plurality of nitride semiconductor layers, grown on the substrate, the nitride semiconductors comprising a first nitride semiconductor layer, to which a first electrode is electrically contacted, a second nitride semiconductor layer, to which a second electrode is electrically connected, and an active layer disposed between the first nitride semiconductor layer and the second nitride semiconductor layer to produce light by re-combination of electrons and holes,
wherein the active layer has a structure comprising quantum well layers and at least one barrier layer which are alternately stacked, in which the number of the quantum well layers is n(n≧2, n is an integer), a iₜₕ quantum well layer (1≦i≦n, i is an integer) from the upper side of the active layer has a band gap energy (Eⱼ) and a barrier layer disposed under a jₜₕ quantum well layer (1≦j≦n−1, j is an integer) is doped, so the kₜₕ quantum well layer (j+1≦k≦n, k is an integer) is inhibited from emitting light having a wavelength corresponding an band gap energy (Eₖ) of the kₜₕ quantum well layer.

2. The method for controlling an active layer of a III-nitride semiconductor light emitting device according to claim 1, wherein the barrier layer disposed under the jₜₕ quantum well layer (1≦j≦n−1, j is an integer) is doped to form a hole barrier layer so that the kₜₕ quantum well layer (j+1≦k≦n, k is an integer) is inhibited from emitting light having a wave length corresponding an band gap energy (Eₖ) of the kₜₕ quantum well layer.

3. The method for controlling an active layer of a III-nitride semiconductor light emitting device according to claim 1, wherein the doping performed on the barrier layer disposed under the jₜₕ quantum well layer (1≦j≦n−1, j is an integer) is an n-type doping.

4. The method for controlling an active layer of a III-nitride semiconductor light emitting device according to claim 1, wherein in addition to the doping performed on the barrier layer disposed under the jₜₕ quantum well layer (1≦j≦n−1, j is an integer), at least one barrier layer disposed under the doped barrier layer is doped so that the kₜₕ quantum well layer (j+1≦k≦n, k is an integer) is inhibited from emitting light having a wave corresponding an band gap energy (Eₖ) of the kₜₕ quantum well layer.

5. The method for controlling an active layer of a III-nitride semiconductor light emitting device according to claim 1, wherein the distance between the jₜₕ quantum well layer (1≦j≦n−1, j is an integer) and the 1ₜₕ quantum well layer is not greater than the distance between the jₜₕ quantum well layer (1≦j≦n−1, j is an integer) and the nₜₕ quantum well layer.

6. The method for controlling an active layer of a III-nitride semiconductor light emitting device according to claim 1, wherein each of the quantum well layers has a thickness of 5 Å to 50 Å.

7. The method for controlling an active layer of a III-nitride semiconductor light emitting device according to claim 1, wherein at least one of the barrier layers has a thickness of 30 Å to 500 Å.

8. The method for controlling an active layer of a III-nitride semiconductor light emitting device according to claim 3, wherein the doped barrier layer has a doping concentration of 5×10¹⁶ to 9×10¹⁹.

9. The method for controlling an active layer of a III-nitride semiconductor light emitting device according to claim 3, wherein the n-type dopant is at least one selected from the group consisting of Si, C, Ge and Sn.

10. The method for controlling an active layer of a III-nitride semiconductor light emitting device according to claim 7, wherein at least one of the barrier layers partially is doped.
